(19) United States
(12) Patent Application Publication
(10) Pub. No.: US 2023/0126956 A1
(43) Pub. Date: Apr. 27, 2023

(54) METHOD FOR MANUFACTURING A THREE-DIMENSIONAL LTCC PACKAGE STRUCTURE

(71) Applicant: Chun-Hsia Chen, Taoyuan City (TW)

(72) Inventor: Chun-Hsia Chen, Taoyuan City (TW)

(73) Assignee: ONANO INDUSTRIAL CORP., Taoyuan City (TW)

(21) Appl. No.: 17/512,600

(22) Filed: Oct. 27, 2021

(51) Int. Cl. H01L 25/00; H01L 23/00; H01L 21/48

(52) U.S. Cl. CPC H01L 25/50; H01L 24/81; H01L 21/486; H01L 21/4857; H01L 2224/81895

(57) ABSTRACT

A method includes the steps of: a) providing an interposer, wherein the interposer has a chamber therein, multiple chip I/O contacts are formed in the chamber, and the chip I/O contacts are connected to connecting wires disposed in the interposer through transmission wires in the interposer; b) placing a semiconductor chip in the chamber and electrically connecting pins of the semiconductor chip to the chip I/O contacts; c) providing a substrate, wherein signal contacts and external contacts are disposed on two sides of the substrate, respectively, and the signal contacts are electrically connected to the external contacts through transmission wires embedded in the substrate; d) superposing the interposer on the substrate to form a combination, wherein the signal contacts of the substrate separately electrically connect with the connecting wires of the interposer; and e) encapsulating the combination with encapsulation adhesive.

### BACKGROUND

### Technical Field

The invention relates to low-temperature co-fired ceramics (LTCC), particularly to a method for manufacturing an LTCC package structure with three-dimensional connecting wires.

### Related Art

Introducing the silicon intermediate package structure can effectively avoid the problem resulting from inconsistent thermal expansion coefficients between a semiconductor and a package substrate to improve the structural stability of packaged products. As shown in FIG. 18, the package structure with a silicon interposer mounts a semiconductor chip 80 on a silicon interposer 90 with a silicon through hole 91. The silicon interposer 90 serves as an adapter plate to electrically connect the semiconductor chip 80 to a package substrate 95.

Such a silicon interposer can overcome the problem of inconsistent thermal expansion coefficients. Also, because of its shorter transmission distance, the electric transmission speed of the semiconductor chip 80 can be increased.

However, both the difficulty of process technology and the processing cost are added because the silicon interposer utilizes the semiconductor manufacture process. With the enhancement of performance of the semiconductor chip 80, the number of input/output (I/O) also increases and the connecting wires circuit of the package structure becomes more complicated, so the planar connecting wires circuit framework of the conventional silicon interposer is gradually inadequate. Accordingly, how to avoid the above problems in the prior art is an urgent issue for the industry.

### SUMMARY

An object of the invention is to provide a method for manufacturing a three-dimensional LTCC package structure, which can reduce the package costs, increase the yield rate of packaged products, raise the setting density of packaged components and minify the volume of packaged products.

Another object of the invention is to provide a method for manufacturing three-dimensional LTCC package structure, which can avoid thermal stress, delaminating of encapsulation adhesive and warpage of packaged products.

Still another object of the invention is to provide a method for manufacturing three-dimensional LTCC package structure, whose ceramic interposer and substrate possess better thermal conductivity, weather resistance, hardness and insulation than conventional silicon interposers and PCB substrates.

To accomplish the above objects, the invention provides a method foe manufacturing a three-dimensional LTCC package structure, which includes the steps of: a) providing an interposer, wherein the interposer has a chamber therein, multiple chip input/output (I/O) contacts are formed in the chamber, and the chip I/O contacts are electrically connected to connecting wires disposed at a peripheral area of the interposer through transmission wires embedded in the interposer; b) placing a semiconductor chip in the chamber and electrically connecting pins of the semiconductor chip to the chip I/O contacts; c) providing a substrate, wherein multiple signal contacts are disposed on a peripheral portion of an upper surface of the substrate, multiple external contacts are disposed on a bottom surface of the substrate, and the signal contacts are electrically connected to the external contacts through transmission wires embedded in the substrate; d) superposing the interposer with the semiconductor chip on the substrate to form a combination, wherein the signal contacts of the substrate separately electrically connect with the connecting wires of the interposer; and e) encapsulating the combination with encapsulation adhesive, wherein the encapsulation adhesive connects with the substrate.

In the present invention, the interposer comprises an upper hollow ceramic layer, a three-dimensional wiring layer and a lower hollow ceramic layer, which are sintered by an LTCC process, each of the upper hollow ceramic layer and the lower hollow ceramic layer has a central cavity and a frame around the central cavity, the connecting wires are disposed in each of the two frames, the transmission wires are disposed in the three-dimensional wiring layer, an end of each transmission wire of the three-dimensional wiring layer is electrically connected to one of chip I/O contacts, and another end thereof is electrically connected to one of the connecting wires.

In the present invention, the three-dimensional wiring layer comprises a wire sublayer and a ceramic sublayer, the wire sublayers and the ceramic sublayers are interlacedly superposed, the transmission wires are horizontally disposed on the wire sublayer, the ceramic sublayer is disposed with a connecting conductor which perpendicularly penetrate through an upper surface and a lower surface of the ceramic sublayer.

In the present invention, each of the wire sublayer and the ceramic sublayer is two in number, and the wire sublayers and the ceramic sublayers are interlacedly superposed.

In the present invention, the wire sublayer is two in number, and the wire sublayers and the ceramic sublayer are interlacedly superposed.

In the present invention, the ceramic sublayer is two in number, and the wire sublayer and the ceramic sublayers are interlacedly superposed.

In the present invention, an end of each transmission wire is electrically connected to one of the chip I/O contacts through one or more connecting conductors, and another end thereof is electrically connected to one of connecting wires.

In the present invention, the substrate comprises a wire layer, a ceramic layer and a base ceramic layer, the wire layers and the ceramic layers are interlacedly superposed, the base ceramic layer is the lowermost layer of the substrate, the ceramic layer which is the uppermost layer of the substrate is provided with multiple signal contacts on the peripheral portion of the upper surface of the ceramic layer, the wire layer has a transmission wire arranged along a horizontal direction, and the base ceramic layer is provided with multiple external contacts which are exposed on a bottom surface.

In the present invention, each of the wire layer and the ceramic layer is two in number, and the wire layers and the ceramic layers are interlacedly superposed.

In the present invention, the wire layer is two in number, and the wire layers and the ceramic layer are interlacedly superposed.

In the present invention, the ceramic layer is two in number, and the wire layer and the ceramic layers are interlacedly superposed.

In the present invention, in the substrate, an end of each transmission wire is electrically connected to one of the signal contacts through one or more connecting conductors, and another end thereof is electrically connected to one of external contacts.

In the present invention, a receiving depth of the chamber is greater than a thickness of the semiconductor chip.

The present invention further comprises another interposer superposed on the interposer, wherein the connecting wires in each interposer electrically connect to each other.

### BRIEF DESCRIPTION OF THE DRAWINGS

FIG. 1 is a schematic view of the package structure of the first embodiment of the invention;

FIG. 2 is a schematic cross-sectional view of the lamination of the interposer of the first embodiment of the invention;

FIG. 3 is a top plan view of the interposer of the first embodiment of the invention;

FIG. 4 is a cross-sectional view of the interposer of the first embodiment of the invention;

FIG. 5 is a schematic cross-sectional view of the lamination of another embodiment of the interposer of the invention;

FIG. 6 is a schematic assembled view of the combination of the interposer and the semiconductor of the first embodiment of the invention;

FIG. 7 is a schematic view of the lamination of the substrate of the first embodiment of the invention;

FIG. 8 is a top plan view of the substrate of the first embodiment of the invention;

FIG. 9 is a bottom plan view of the substrate of the first embodiment of the invention;

FIG. 10 is a cross-sectional view of the substrate of the first embodiment of the invention;

FIG. 11 is a schematic cross-sectional view of the lamination of another embodiment of the substrate of the invention;

FIG. 12 is a cross-sectional view of the combination of the interposer, the semiconductor chip and the substrate of the first embodiment of the interposer of the invention;

FIG. 13 is a schematic view of the package structure which has been packaged with adhesive of the first embodiment of the invention;

FIG. 14 is a schematic view of the package structure of the second embodiment of the invention;

FIG. 15 is a schematic view of the package structure of the third embodiment of the invention;

FIG. 16 is a plan view of the third embodiment of the invention, which shows multiple semiconductors are installed in the upper chamber with an enlarged width;

FIG. 17 is a schematic view of the package structure of the fourth embodiment of the invention; and

FIG. 18 is a schematic view of a conventional package structure using a silicon interposer.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

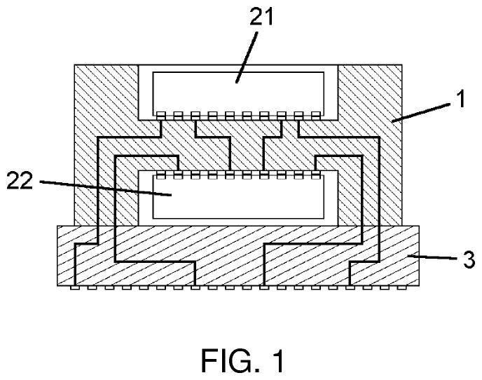

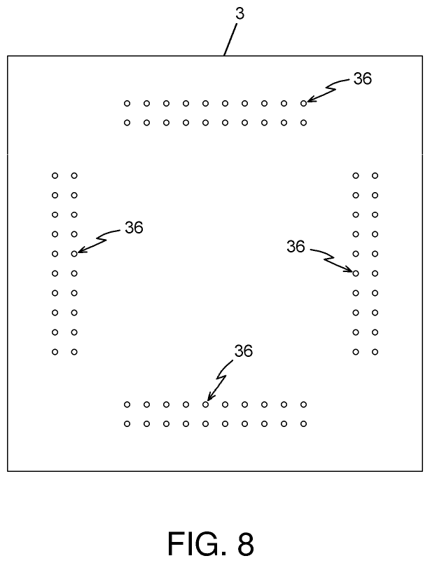

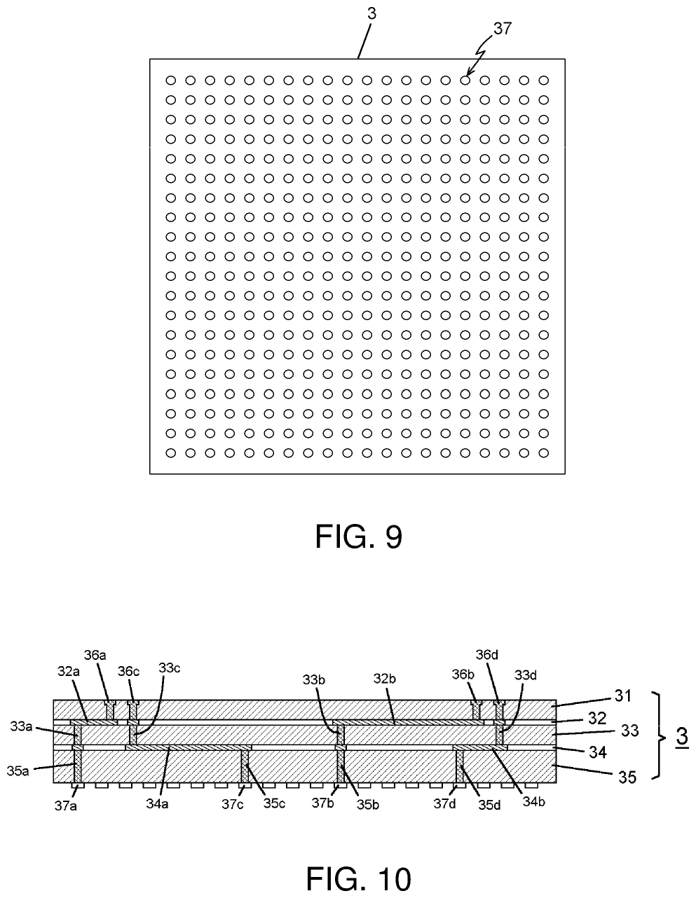

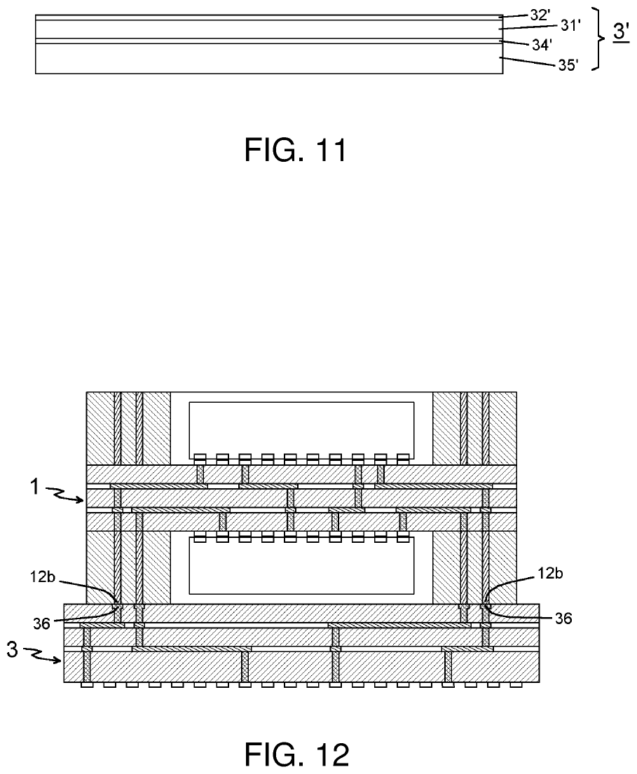

FIGS. 1-13 depict the first embodiment of the three-dimensional LTCC package structure of the invention. The first embodiment is the most simplified package structure.

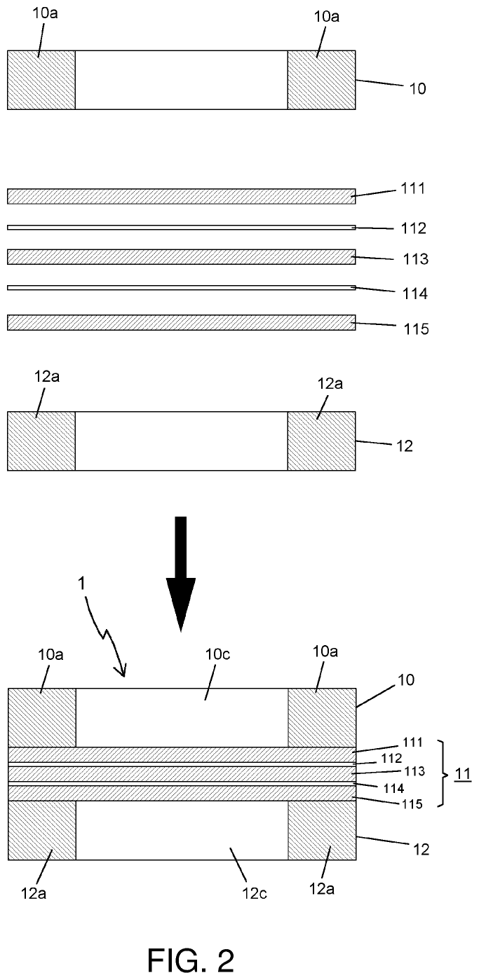

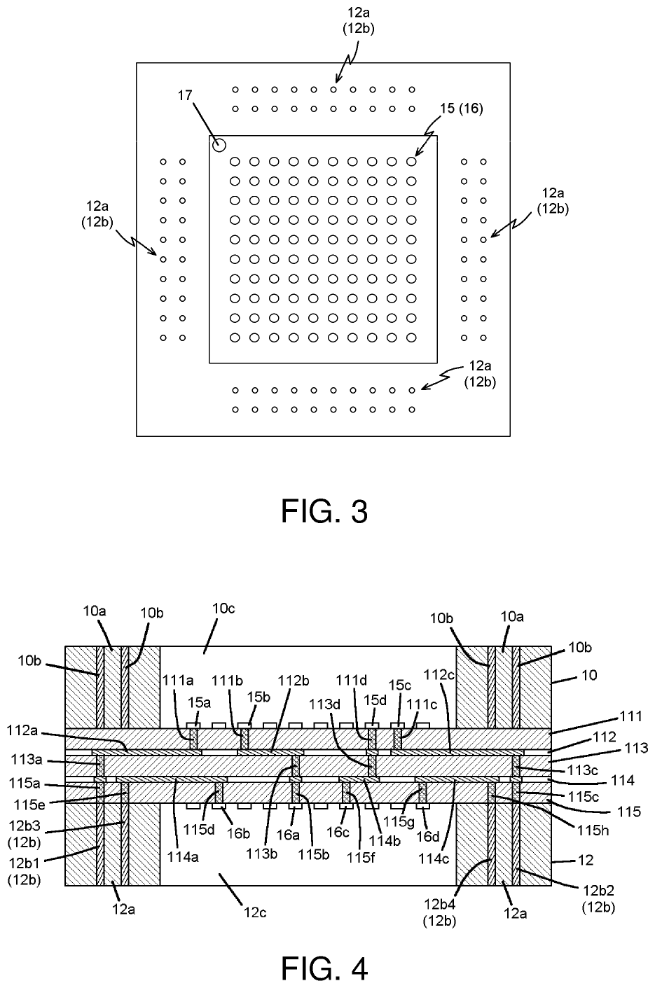

Please refer to FIGS. 2-4. In the first step, the method of the invention provides an interposer 1. The interposer 1 is a hollow frame with a three-dimensional connecting wires framework. The interposer 1 is composed of an upper hollow ceramic layer 10, a three-dimensional wiring layer 11 and a lower hollow ceramic layer 12, which are combined by the processes of stacking, lamination, knife cutting, burn-out and sintering. Each of the upper hollow ceramic layer 10 and the lower hollow ceramic layer 12 has a central cavity and a frame 10a, 12a around the central cavity as shown in FIGS. 2 and 3. Multiple connecting wires 10b, 12b are disposed in the two frames 10a, 12a. As shown in FIG. 4, the connecting wires 10b, 12b perpendicularly penetrate through the upper surfaces and the lower surfaces of the frames 10a, 12a. After the upper hollow ceramic layer 10, the three-dimensional wiring layer 11 and the lower hollow ceramic layer 12 have been superposed and combined, an upper portion of the interposer 1 is formed with an upper chamber 10c which is downward dented and a lower portion of the interposer 1 is formed with a lower chamber 12c which is upward dented. The upper chamber 10c and the lower chamber 12c may be used for receiving a semiconductor chip. Multiple chip input/output (I/O) contacts 15, 16 and at least one adhesive filling hole 17 are formed in each of the upper chamber 10c and the lower chamber 12c. The adhesive filling hole 17 penetrates through the plate and makes the upper chamber 10c and the lower chamber 12c communicate with each other.

The three-dimensional wiring layer 11 includes at least one wire sublayer and at least one ceramic sublayer. The wire sublayer is formed on the ceramic layer. The wire sublayers and the ceramic sublayers are interlacedly superposed. The wire sublayer has transmission wires which are horizontally arranged and disposed on the ceramic sublayer by the yellow light process or the screen printing. The ceramic sublayer is disposed with connecting conductors which perpendicularly penetrate through an upper surface and a lower surface of the ceramic sublayer. The connecting conductors electrically connect the transmission wires or contacts, which are located on different layers. As a result, a three-dimensional connection is formed in the interposer.

Please refer to FIG. 4, in the first embodiment of the invention, the three-dimensional wiring layer 11 includes a first ceramic sublayer 111, a first wire sublayer 112, a second ceramic sublayer 113, a second wire sublayer 114 and a third ceramic sublayer 115. According to the design requirements, each ceramic sublayer 111, 113, 115 is disposed with multiple connecting conductors at corresponding positions. For example, the first transmission wire 112a on the first wire sublayer 112 is electrically connected both to the upper chip I/O contact 15a through the connecting conductor 111a and to the connecting wire 12b1 of the lower hollow ceramic layer 12 through the connecting conductors 113a, 115a; the second transmission wire 112b on the first wire sublayer 112 is electrically connected both to the upper chip I/O contact 15b through the connecting conductor 111b and to the lower chip I/O contact 16a through the connecting conductors 113b, 115b; the third transmission wire 112c on the first wire sublayer 112 is electrically connected both to the upper chip I/O contact 15c through the connecting conductor 111c and to the connecting wire 12b2 of the lower hollow ceramic layer 12 through the connecting conductors 113c, 115c; the first transmission wire 114a on the second wire sublayer 114 is electrically connected both to the lower chip I/O contact 16b through the connecting conductor 115d and to the connecting wire 12b3 of the lower hollow ceramic layer 12 through the connecting conductors 115e; the second transmission wire 114b on the second wire sublayer 114 is electrically connected both to the upper chip I/O contact 15d through the connecting conductor 113d, 111d and to the lower chip I/O contact 16c through the connecting conductors 115f; and the third transmission wire 114c on the second wire sublayer 114 is electrically connected both to the lower chip I/O contact 16d through the connecting conductor 115g and to the connecting wire 12b4 of the lower hollow ceramic layer 12 through the connecting conductors 115h.

In the first embodiment of the invention, the three-dimensional wiring layer 11 has two wire sublayers and three ceramic sublayers. In practice, however, the number of the sublayers is not limited. When the three-dimensional wiring layer 11 has more sublayers, it means the interposer may provide more chip I/O contacts to integrate more semiconductor chips and various electronic components.

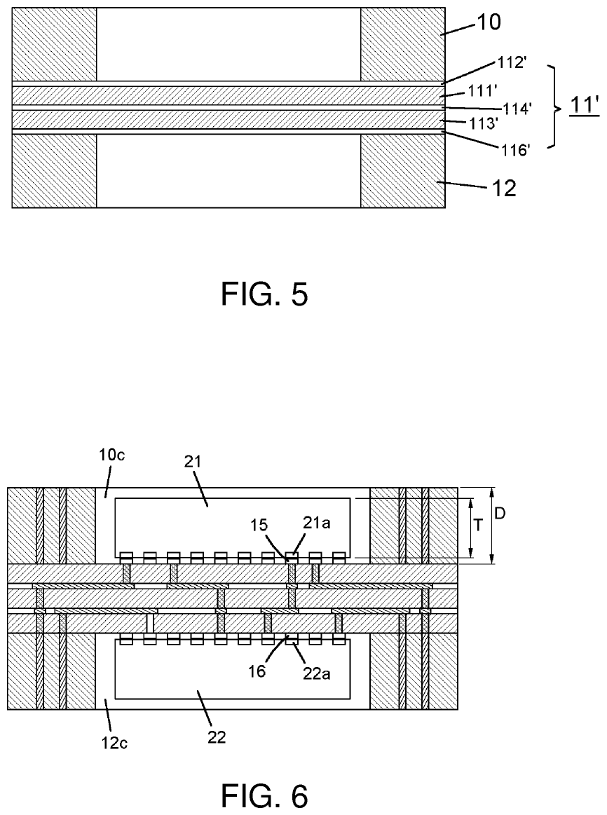

Please refer to FIG. 5, which shows another available solution of the interposer structure. In the embodiment, the three-dimensional wiring layer 11′ has three wire sublayers and two ceramic sublayers. The three-dimensional wiring layer 11′ includes a first wire sublayer 112′, a first ceramic sublayer 111′, a second wire sublayer 114′, a second ceramic sublayer 113′ and a third wire sublayer 116′. The first wire sublayer 112′ is disposed on an upper surface of the first ceramic sublayer 111′. The second wire sublayer 114′ is disposed between the first ceramic sublayer 111′ and the second ceramic sublayer 113′. The third wire sublayer 116′ is disposed on a lower surface of the second ceramic sublayer 113′. Identically to the first embodiment, according to the design requirements, each ceramic sublayer 111′, 113′ is disposed with multiple connecting conductors at corresponding positions. The connecting conductors electrically connect the transmission wires or contacts, which are located on different layers.

As a result, a three-dimensional connection is formed in the interposer. In comparison with the first embodiment, the three-dimensional wiring layer 11′ has more wire sublayers and less ceramic sublayers, this can save processing costs and material costs, increase the amount of the chip I/O contacts and improve the performance of the connecting wires.

Please refer to FIG. 6. In the second step of the invention, a first semiconductor chip 21 is disposed in the upper chamber 10c of the interposer 1 and connected with the chip I/O contacts 15 by micro bumps. Pins 21a of the first semiconductor chip 21 are separately electrically connected with and fixed to the chip I/O contacts 15. Identically, a second semiconductor chip 22 is disposed in the lower chamber 12c of the interposer 1 and connected with the chip I/O contacts 16 by micro bumps. Pins 22a of the second semiconductor chip 22 are separately electrically connected with and fixed to the chip I/O contacts 16. It is noted that a receiving depth of each of the upper chamber 10c and the lower chamber 12c must be greater than a thickness of each semiconductor chip 21, 22 to prevent the semiconductor chips 21, 22 from protruding from the chambers 10c, 12c. This guarantees that the interposer can be assembled with another interposer or a substrate.

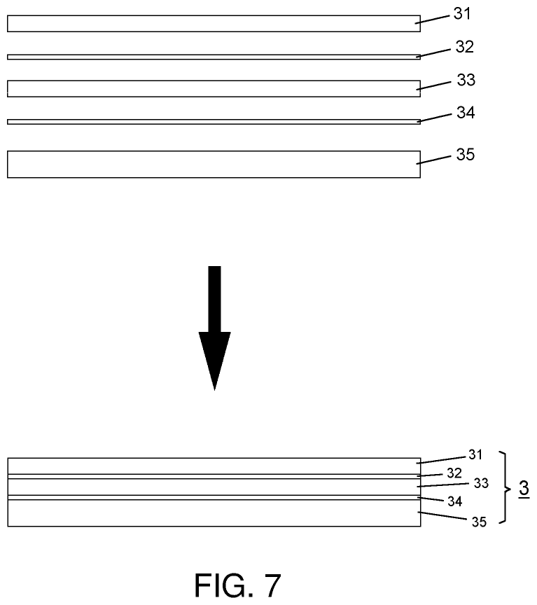

Please refer to FIGS. 7-10. In the third step of the invention, a substrate 3 with a three-dimensional connection framework is provided. The substrate 3 includes at least one wire layer, at least one ceramic layer and a base ceramic layer. The wire layer is formed on the ceramic layer. The wire layers and the ceramic layers are interlacedly superposed. The wire layer has transmission wires which are horizontally arranged and disposed on the ceramic layer by the yellow light process or the screen printing. Multiple external contacts are disposed on the base ceramic layer. The ceramic layer is formed with connecting conductors which perpendicularly penetrate through an upper surface and a lower surface of the ceramic layer. The connecting conductors electrically connect the transmission wires or contacts, which are located on different layers. As a result, a three-dimensional connection is formed in the substrate.

Please refer to FIG. 10. In the first embodiment of the invention, the substrate 3 is composed of a first ceramic layer 31, a first wire layer 32, a second ceramic layer 33, a second wire layer 34 and a base ceramic sublayer 35, which are combined by the processes of stacking, lamination, knife cutting, burn-out and sintering. A peripheral area of an upper surface of the first ceramic layer 31 which is the upmost layer of the substrate 3, is provided with multiple signal contacts 36. The base ceramic layer 35 is provided with multiple external contacts 37 which are exposed on the bottom surface. According to the design requirements, each ceramic layer 31, 33, 35 is disposed with multiple connecting conductors at corresponding positions. For example, the first transmission wire 32a on the first wire layer 32 is electrically connected both to the signal contact 36a and to the external contact 37a of the bottom through the connecting conductors 33a, 35a; the second transmission wire 32b on the first wire layer 32 is electrically connected both to the signal contact 36b and to the external contact 37b of the bottom through the connecting conductors 33b, 35b; the first transmission wire 34a on the second wire layer 34 is electrically connected both to the signal contact 36c through the connecting conductor 33c and to the external contact 37c of the bottom through the connecting conductors 35c; and the second transmission wire 34b on the second wire layer 34 is electrically connected both to the signal contact 36d through the connecting conductor 33d and to the external contact 37d of the bottom through the connecting conductors 35d.

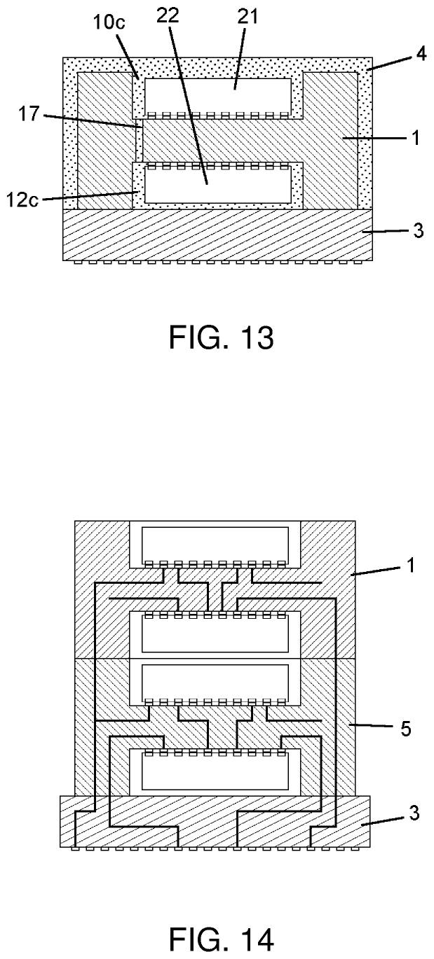

Please refer to FIG. 12. In the fourth step of the invention, the substrate 3 is superposed under the interposer 1 and the connecting wires 12b at a lower portion of the interposer 1 separately electrically connect with corresponding one of the signal contacts 36 of the substrate 3. Finally, in the fifth step of the invention, the interposer 1 and the semiconductor chips 21, 22 are covered by encapsulation adhesive 4 and the substrate 3. The interposer 1 and the semiconductor chips 21, 22 are completely encapsulated by the encapsulation adhesive 4 and encapsulation adhesive 4 connects with the substrate 3. As shown in FIG. 13, the encapsulation adhesive 4 is filled into the lower chamber 12c through the adhesive filling hole 17 of the interposer 1.

The substrate 3 of the first embodiment of the invention has two wire layers and three ceramic layers. In practice, however, the number of the sublayers is not limited. Please refer to FIG. 5, which shows another available solution of the substrate structure. In the embodiment, the substrate 3′ has two wire layers and two ceramic layers. The substrate 3′ includes a first wire layer 32′, a first ceramic layer 31′, a second wire layer 34′ and a base ceramic layer 35′. The first wire layer 32′ is disposed on an upper surface of the first ceramic layer 31′. The second wire layer 34′ is disposed between the first ceramic layer 31′ and the base ceramic layer 35′. Identically to the first embodiment, according to the design requirements, each ceramic layer 31′, 35′ is disposed with multiple connecting conductors at corresponding positions. The connecting conductors electrically connect the transmission wires or contacts, which are located on different layers. As a result, a three-dimensional connection is formed in the substrate. In comparison with the first embodiment, the substrate 3′ has less ceramic layers, this can save processing costs and material costs.

Please refer to FIG. 14, which shows the second embodiment of the invention. The second embodiment adds a second interposer 5 in the package structure of the first embodiment. The second interposer 5 is disposed between the interposer 1 and the substrate 3 of the first embodiment. The second interposer 5 may be installed with multiple semiconductor chips or other electronic components.

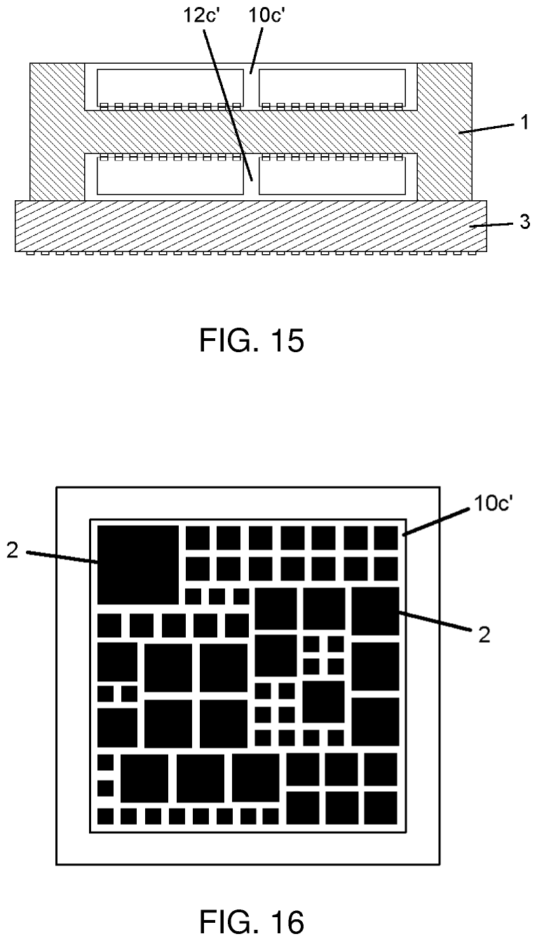

Please refer to FIG. 15, which shows the third embodiment of the invention. The third embodiment is based on the second embodiment. The difference is that the interposer 1 has an upper chamber 10c′ and a lower chamber 12c′, each of which has an enlarged width. The chambers 10c′, 12c′ with enlarged widths may be installed with more semiconductor chips or other electronic components. FIG. 16 further depicts an embodiment, the upper chamber 10c′ with an enlarged width is assembled with dozens of semiconductor chips 2 with different sizes.

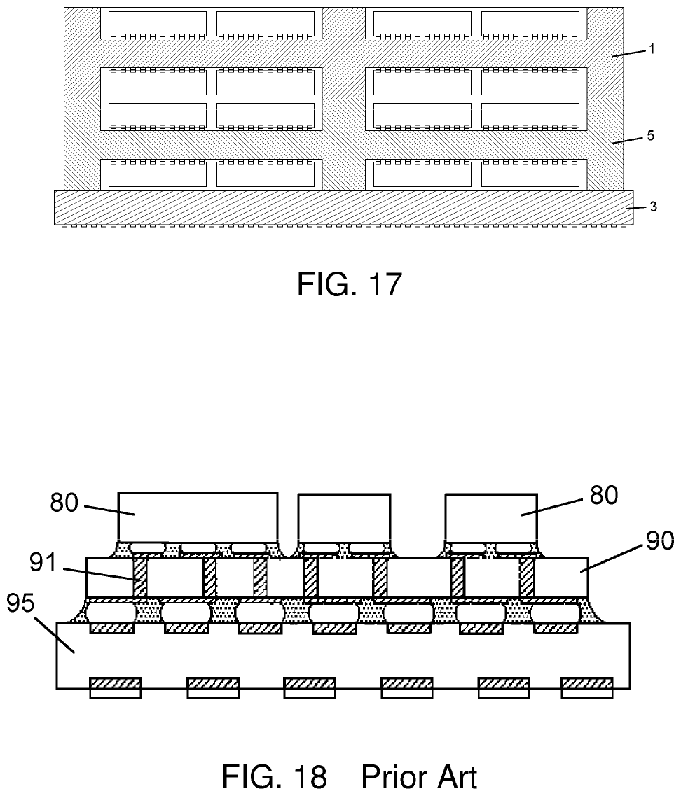

Please refer to FIG. 17, which shows the fourth embodiment of the invention. The fourth embodiment is based on the second and third embodiments. The difference is that each interposer 1, 5 has multiple chambers for receiving a double amount of semiconductor chips or other electronic components.

While this disclosure has been described by means of specific embodiments, numerous modifications and variations could be made thereto by those skilled in the art without departing from the scope and spirit of this disclosure set forth in the claims.

What is claimed is:

1. A method for manufacturing a three-dimensional low-temperature co-fired ceramics (LTCC) package structure, the method comprising:
a) providing an interposer, wherein the interposer has a chamber therein, multiple chip input/output (I/O) contacts are formed in the chamber, and the chip I/O contacts are electrically connected to connecting wires disposed at a peripheral area of the interposer through transmission wires embedded in the interposer;
b) placing a semiconductor chip in the chamber and electrically connecting pins of the semiconductor chip to the chip I/O contacts;
c) providing a substrate, wherein multiple signal contacts are disposed on a peripheral portion of an upper surface of the substrate, multiple external contacts are disposed on a bottom surface of the substrate, and the signal contacts are electrically connected to the external contacts through transmission wires embedded in the substrate;
d) superposing the interposer with the semiconductor chip on the substrate to form a combination, wherein the signal contacts of the substrate separately electrically connect with the connecting wires of the interposer; and
e) encapsulating the combination with encapsulation adhesive, wherein the encapsulation adhesive connects with the substrate.

2. The method of claim 1, wherein the interposer comprises an upper hollow ceramic layer, a three-dimensional wiring layer and a lower hollow ceramic layer, which are sintered by an LTCC process, each of the upper hollow ceramic layer and the lower hollow ceramic layer has a central hole cavity and a frame around the central cavity, the connecting wires are disposed in each of the two frames, the transmission wires are disposed in the three-dimensional wiring layer, an end of each transmission wire of the three-dimensional wiring layer is electrically connected to one of chip I/O contacts, and another end thereof is electrically connected to one of the connecting wires.

3. The method of claim 2, wherein the three-dimensional wiring layer comprises a wire sublayer and a ceramic sublayer, the wire sublayers and the ceramic sublayers are interlacedly superposed, the transmission wires are horizontally disposed on the wire sublayer, the ceramic sublayer is disposed with a connecting conductor which perpendicularly penetrate through an upper surface and a lower surface of the ceramic sublayer.

4. The method of claim 3, wherein each of the wire sublayer and the ceramic sublayer is two in number, and the wire sublayers and the ceramic sublayers are interlacedly superposed.

5. The method of claim 3, wherein the wire sublayer is two in number, and the wire sublayers and the ceramic sublayer are interlacedly superposed.

6. The method of claim 3, wherein the ceramic sublayer is two in number, and the wire sublayer and the ceramic sublayers are interlacedly superposed.

7. The method of claim 3, wherein an end of each transmission wire is electrically connected to one of the chip I/O contacts through one or more connecting conductors, and another end thereof is electrically connected to one of connecting wires.

8. The method of claim 1, wherein the substrate comprises a wire layer, a ceramic layer and a base ceramic layer, the wire layers and the ceramic layers are interlacedly superposed, the base ceramic layer is the lowermost layer of the substrate, the ceramic layer is provided with a connecting conductor which perpendicularly penetrates through an upper surface and a lower surface of the ceramic layer, and the ceramic layer which is the uppermost layer of the substrate is provided with multiple signal contacts on the peripheral portion of the upper surface of the ceramic layer, the wire layer has a transmission wire arranged along a horizontal direction, and the base ceramic layer is provided with multiple external contacts which are exposed on a bottom surface.

9. The method of claim 8, wherein in the substrate, an end of each transmission wire is electrically connected to one of the signal contacts through one or more connecting conductors, and another end thereof is electrically connected to one of external contacts.

10. The method of claim 8, wherein each of the wire layer and the ceramic layer is two in number, and the wire layers and the ceramic layers are interlacedly superposed.

11. The method of claim 8, wherein the wire layer is two in number, and the wire layers and the ceramic layer are interlacedly superposed.

12. The method of claim 8, wherein the ceramic layer is two in number, and the wire layer and the ceramic layers are interlacedly superposed.

13. The method of claim 1, wherein a receiving depth of the chamber is greater than a thickness of the semiconductor chip.

14. The method of claim 1, further comprising another interposer superposed on the interposer, wherein the connecting wires in each interposer electrically connect to each other.
